(19) United States
(12) Patent Application Publication
(10) Pub. No.: US 2003/0080440 A1
(43) Pub. Date: May 1, 2003

(54) REVERSE CONTRAST MARKED PACKAGE

(75) Inventors: Mr. Jeffrey Alan Miks, Chandler, AZ (US); Miss Eulogia Niones Anderson, Chandler, AZ (US); Mr. KiWoo Jang, Inchon (KR); Mr. ChanHa Hwang, Inchon (KR)

Correspondence Address: Gunnison, McKay & Hodgson, LLP, Serge J. Hodgson, 1900 Garden Road, Suite 220, Monterey, CA, 93940, US

(73) Assignee: Amkor Technology, Inc., Chandler, 85248 (US)

(21) Appl. No.: 09/585,704

(22) Filed: May 31, 2000

(51) Int. Cl. H01L 23/544; H01L 21/56

(52) U.S. Cl. 257/787; 257/790; 257/794; 257/797; 438/401; 438/462; 264/272.17; 264/132

(57) ABSTRACT

### Abstract of Disclosure

A package includes a white contrast layer on an upper surface of a black encapsulant. A mark is in the white contrast layer and extends through the white contrast layer such that the black encapsulant is visible through the mark. Since the black encapsulant is visible through the mark, the mark has a high contrast relative to the white contrast layer and is extremely effective as an advertisement or as a package identification mark.

### Background of Invention

As is well known to those of skill in the art, electronic components such as integrated circuits were packaged. During this packaging process, the electronic component was sealed in an encapsulant, e.g., a plastic or liquid encapsulant.

The resultant package (hereinafter referred to as a package), which included the electronic component, was marked for part identification and/or for other reasons. Typically, the encapsulant of the package was marked. For example, the package was marked to identify the part number associated with the package or for advertisement.

FIG. 1 is a top plan view of a package 10 having an ink mark 14 in accordance with the prior art. Package 10 included an upper surface 12 formed of encapsulant. Generally, upper surface 12 was planar. Ink mark 14 was formed on upper surface 12. As shown in FIG. 1, ink mark 14 was the words "Amkor Technology", which was an advertisement for the manufacturer of package 10, i.e., Amkor Technology, Inc.

Since the encapsulant of package 10 was black, upper surface 12 was black. Ink mark 14 was formed of a white ink, which had a high contrast to upper surface 12. In this manner, the manufacturer"s advertisement, i.e., ink mark 14, was easily visible and stood out.

Ink mark 14 was formed using a pad ink marking method, sometimes called ink stamping, well known to those of skill in the art. First, a metal stencil was formed by etching the pattern of ink mark 14 into a metal plate. Ink was applied to the metal stencil. This ink was transferred from the metal stencil to a printing pad formed of a compliant rubber. The printing pad was then pressed against upper surface 12 to transfer the ink from the printing pad to upper surface 12. The ink on upper surface 12 was then cured by heating to form ink mark 14.

In the event that a different pattern than that of ink mark 14 was to be formed, e.g., for a different manufacturer or a different part number, a new metal stencil had to be fabricated. Disadvantageously, metal stencil fabrication involved metal etching, which was relatively complex, labor-intensive, time-consuming, and thus expensive.

To avoid the expensive associated with metal stencil fabrication for each new pattern, a laser was used to mark the upper surface of the package. FIG. 2 is a top plan view of a package 20 having a laser mark 24 in accordance with the prior art. Package 20 of FIG. 2 was substantially similar to package 10 of FIG. 1 and only the significant differences are discussed below.

Referring now to FIG. 2, package 20 included laser mark 24. Laser mark 24 was the words "Amkor Technology", which was an advertisement for the manufacturer of package 20, i.e., Amkor Technology, Inc.

Laser mark 24 was formed using a laser marking apparatus as is well known to those of skill in the art. Generally, the pattern of laser mark 24 was loaded as software into the laser marking apparatus. Based on this software, a laser was fired at upper surface 12 to laser ablate, sometimes called burn in, laser mark 24 into upper surface 12.

Advantageously, formation of laser mark 24 of package 20 of FIG. 2 was more reliable, less labor-intensive, and less expensive than formation of ink mark 14 of package 10 of FIG. 1. Further, changing to a different pattern than that of laser mark 24 involved only some relatively simple computer programming of the laser marking apparatus as compared to the formation of a new metal stencil for pad ink marking.

However, laser mark 24 was only an etching into upper surface 12. Accordingly, laser mark 24 was similar in color to the color of upper surface 12, e.g., upper surface 12 was black and laser mark 24 was blackish gold. Thus, laser mark 24 lacked contrast and was difficult to see. For example, when viewed at an angle in dim light, laser mark 24 was essentially invisible.

To be effective, an advertisement or part identification marking must be visible. Since laser mark 24 was essentially invisible depending upon the ambient conditions, laser mark 24 was thought to be ineffective as an advertisement or as a part identification marking. For this reason, many manufacturers required the package to be marked with an ink mark similar to ink mark 14 of package 10 of FIG. 1.

### Summary of Invention

In accordance with the present invention, a package includes an electronic component enclosed in an encapsulant. The encapsulant has an upper surface and a contrast layer is on the upper surface. A mark is in the contrast layer and extends through the contrast layer such that the encapsulant is visible through the mark.

Generally, the contrast layer has a contrast relative to the encapsulant. In one particular embodiment, the contrast layer is white and the encapsulant is black. Since the black encapsulant is visible through the mark, the mark is the color of the encapsulant, i.e., black. Since the black encapsulant has a high contrast relative to the white contrast layer, the mark also has a high contrast to the contrast layer. Advantageously, the mark is highly visible under all ambient conditions, even when viewed at an angle under dim light. Accordingly, the mark is highly effective as an advertisement or as a part identification marking.

Also in accordance with the present invention, a method of forming a package includes applying ink to an upper surface of an encapsulant. A contrast layer is formed on the upper surface of the encapsulant from the ink, e.g., by curing the ink. A mark is formed in the contrast layer, the encapsulant being visible through the mark.

In one embodiment, the ink is applied to the upper surface of the encapsulant by transferring the ink from a lower surface of a compliant pad of an ink marking apparatus. Advantageously, the lower surface of the compliant pad is smooth, i.e., is formed without a pattern. Accordingly, the compliant pad can be used with any one of a number of packages. In this manner, custom tooling associated with pad ink marking of the prior art is avoided. The ink is heat cured to form the contrast layer.

A laser of a laser marking apparatus is fired at the contrast layer to form the mark in the contrast layer. The laser penetrates through the contrast layer and into the upper surface of the encapsulant such that the encapsulant is visible through the mark. Since the encapsulant, e.g., black, has a high contrast relative to the contrast layer, e.g., white, the mark is highly visible and is extremely effective as an advertisement or part identification marking.

Advantageously, changing to a different pattern than that of the mark, e.g., to change advertisements or part identification marks, involves only some relatively simple computer programming of the laser marking apparatus as compared to the formation of a new metal stencil for pad ink marking as in the prior art. Thus the method in accordance with the present invention is well suited for use in applications where the pattern of the mark frequently changes. For example, the mark frequently changes in applications involving advertisement by manufacturers.

These and other features and advantages of the present invention will be more readily apparent from the detailed description set forth below taken in conjunction with the accompanying drawings.

### Brief Description of Drawings

FIG. 1 is a top plan view of a package having an ink mark in accordance with the prior art.

FIG. 2 is a top plan view of a package having a laser mark in accordance with the prior art.

FIG. 3 is a top plan view of a package in accordance with the present invention.

FIG. 4 is a cross-sectional view of the package along the line IV-IV of FIG. 3.

FIG. 5 is a cross-sectional of a package during fabrication in accordance with one embodiment of the present invention.

FIG. 6 is a cross-sectional of the package of FIG. 5 at a further stage of fabrication.

In the following description, the same or similar elements are labeled with the same or similar reference numbers.

### Detailed Description

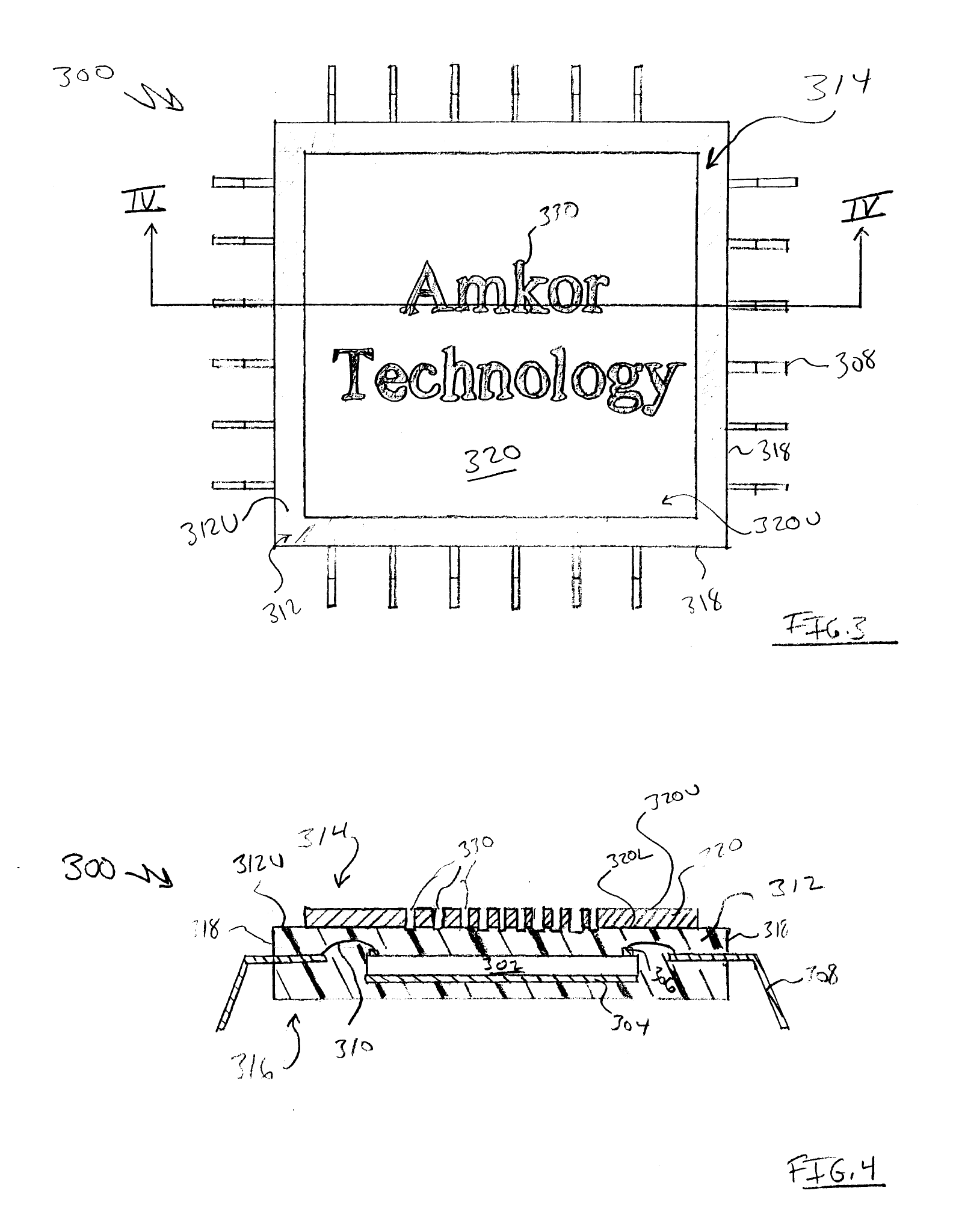

In accordance with the present invention, a package 300 (FIGS. 3 and 4) includes an electronic component 302 enclosed in an encapsulant 312. Encapsulant 312 has an upper surface 312U and a contrast layer 320 is on upper surface 312U. A mark 330 is in contrast layer 320 and extends through contrast layer 320 such that encapsulant 312 is visible through mark 330.

Generally, contrast layer 320 has a contrast relative to encapsulant 312. In one particular embodiment, contrast layer 320 is white and encapsulant 312 is black. Since encapsulant 312 is visible through mark 330, mark 330 is the color of encapsulant 312, i.e., black. Since encapsulant 312 has a high contrast relative to contrast layer 320, mark 330 also has a high contrast to contrast layer 320. Advantageously, mark 330 is highly visible under all ambient conditions, even when viewed at an angle under dim light. Accordingly, mark 330 is highly effective as an advertisement or as a part identification mark.

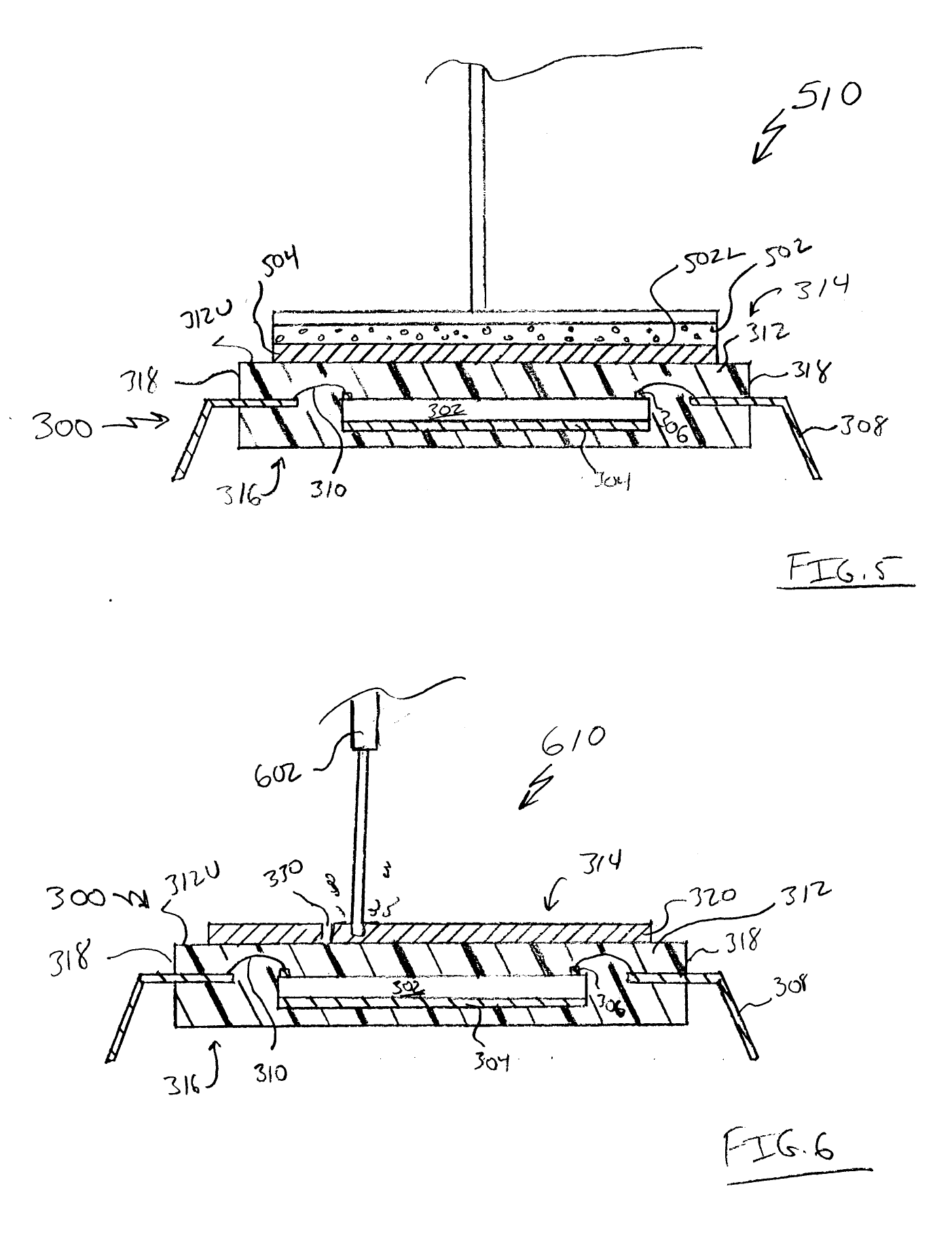

Also in accordance with the present invention, a method of forming package 300 (FIGS. 5 and 6) includes applying ink 504 to upper surface 312U of encapsulant 312. Contrast layer 320 is formed on upper surface 312U of encapsulant 312 from ink 504, e.g., by curing ink 504. A mark 330 is formed in contrast layer 320 by a laser 602 of a laser marking apparatus 610, encapsulant 312 being visible through mark 330.

Advantageously, ink 504 (FIG. 5) is transferred to upper surface 312U of encapsulant 312 by a compliant pad 502 having a smooth lower surface 502L, i.e., formed without a pattern. Accordingly, compliant pad 502 can be used with any one of a number of packages. In this manner, custom tooling associated with pad ink marking of the prior art is avoided.

Advantageously, changing to a different pattern than that of mark 330, e.g., to change advertisements or part identification marks, involves only some relatively simple computer programming of laser marking apparatus 610 as compared to the formation of a new metal stencil for pad ink marking as in the prior art. Thus the method in accordance with the present invention is well suited for use in applications where the pattern of mark 330 frequently changes. For example, the pattern of mark 330 frequently changes in applications involving advertisement by manufacturers.

More particularly, FIG. 3 is a top plan view of a package 300 in accordance with the present invention. FIG. 4 is a cross-sectional view of package 300 along the line IV-IV of FIG. 3. Referring now to FIGS. 3 and 4 together, package 300 includes an electronic component 302 such as an integrated circuit. Electronic component 302 is mounted to a die attach pad 304. Bond pads 306 of electronic component 302 are electrically connected to leads 308 by bond wires 310.

An encapsulant 312, e.g., a cured liquid or plastic encapsulant, encloses electronic component 302, die attach pad 304, bond pads 306, bond wires 310 and the inner ends of leads 308.

Generally, package 300 includes an exposed, e.g., first, surface 314 and a hidden, e.g., second, surface 316. For example, package 300 is mounted to a printed circuit mother board with hidden surface 316 facing towards the printed circuit mother board such that hidden surface 316 is not visible and with exposed surface 314 facing away from the printed circuit board such that exposed surface 314 is visible. Package 300 further includes sides 318 extending between exposed surface 314 and hidden surface 316.

In this embodiment, package 300 is a leadframe type package. More particularly, leads 308 extend from sides 318 of package 300. However, package 300 is another type of package in other embodiments. For example, package 300 is a ball grid array (BGA) type package having a plurality of interconnection balls, e.g., solder balls, arranged in an array on hidden surface 316. Alternatively, package 300 is a land grid array (LGA) type package having a plurality of lands arranged in an array on hidden surface 316. As a further alternative, package 300 is a leadless chip carrier (LCC) type package.

Further, instead of having electronic component 302 encapsulated in encapsulant 312, in an alternative embodiment, electronic component 302 is located within a cavity and package 300 is a cavity type package. For example, package 300 is a ceramic style hermetic package having a ceramic lid hermetically sealed around electronic component 302 as those of skill in the art will understand. In accordance with this embodiment, contrast layer 320 and mark 330 are formed on the ceramic lid of package 300 or elsewhere on package 300.

Alternatively, package 300 is a metal can style package having a metal lid hermetically sealed around electronic component 302 as those of skill in the art will understand. In accordance with this embodiment, contrast layer 320 and mark 330 are formed on the metal lid of package 300 or elsewhere on package 300.

As a further alternative, package 300 is an image sensor package having a glass lid above electronic component 302 as those of skill in the art will understand. In accordance with this embodiment, contrast layer 320 and mark 330 are formed on the glass lid of package 300 or elsewhere on package 300.

In light of this disclosure, those of skill in the art will understand that a variety of package types can be fabricated in accordance with the present invention. The particular type of package is not essential to the invention.

In this embodiment, referring again to FIGS. 3 and 4, exposed surface 314 is defined by an upper, e.g., first, surface 312U of encapsulant 312. Upper surface 312U and exposed surface 314 are planar. Further, hidden surface 316 is planar.

Formed on upper surface 312U is a contrast layer 320. For example, contrast layer 320 is a cured layer of ink. However, in light of this disclosure, those of skill in the art will understand that generally contrast layer 320 is a coating, which can be formed of other materials beside ink.

In this embodiment, contrast layer 320 is formed on a central region of upper surface 312U such that a peripheral region of upper surface 312U directly adjacent sides 318 is not covered by contrast layer 320 and exposed. However, in an alternative embodiment, contrast layer 320 entirely covers upper surface 312U. Further, in this embodiment, contrast layer 320 is rectangular when viewed from above (see FIG. 3), e.g., square. However, in other embodiments, contrast layer 320 has other shapes when viewed from above, e.g., contrast layer 320 is circular or has at least one straight edge.

Generally, contrast layer 320 has a contrast relative to encapsulant 312. More particularly, when viewed, e.g., by a human eye, contrast layer 320 exhibits a difference compared to encapsulant 312. To illustrate, encapsulant 312 is dark in color and contrast layer 320 is light in color. As an example, encapsulant 312 is black and contrast layer 320 is white, yellow, or hot pink although encapsulant 312 and contrast layer 320 have different colors in different embodiments.

Formed in contrast layer 320 is a mark 330, i.e., a pattern. In this embodiment, mark 330 is the words "Amkor Technology", which is an advertisement for the manufacturer of package 300, i.e., Amkor Technology, Inc. However, in light of this disclosure, it is understood that mark 330 can be essentially any pattern.

As best shown in FIG. 4, a lower, e.g., first, surface 320L of contrast layer 320 is on encapsulant 312, and, more particularly, on upper surface 312U of encapsulant 312. An upper, e.g., second, surface 320U of contrast layer 320 is exposed to the ambient environment. Mark 330 is an etching in contrast layer 320, which extends from upper surface 320U to lower surface 320L of contrast layer 320 and to encapsulant 312.

Since encapsulant 312 is visible through mark 330, mark 330 is the color of encapsulant 312, e.g., black. Since encapsulant 312 has a high contrast relative to contrast layer 320, mark 330 also has a high contrast to contrast layer 320. Advantageously, mark 330 is highly visible under all ambient conditions, even when viewed at an angle under dim light. Accordingly, mark 330 is highly effective as an advertisement or as a part identification mark.

Although encapsulant 312 is set forth as the body, which is visible through mark 330, in light of this disclosure, those of skill in the art will understand that other bodies are used in alternative embodiments. For example, instead of encapsulant 312, the body is: ceramic, e.g., a ceramic lid of a ceramic style hermetic package; glass, e.g., a glass lid of an image sensor package; plastic; metal, e.g., a metal lid of a metal can style package; solder mask, e.g., on a printed circuit board substrate; silicon; wafer; and/or printed circuit board.

As a further alternative, contrast layer 320 and mark 330 are on hidden surface 316 instead of exposed surface 314. Further, in another embodiment, contrast layer 320 and mark 330 are on exposed surface 314 and a second contrast layer 320 and a second mark 330 are on hidden surface 316.

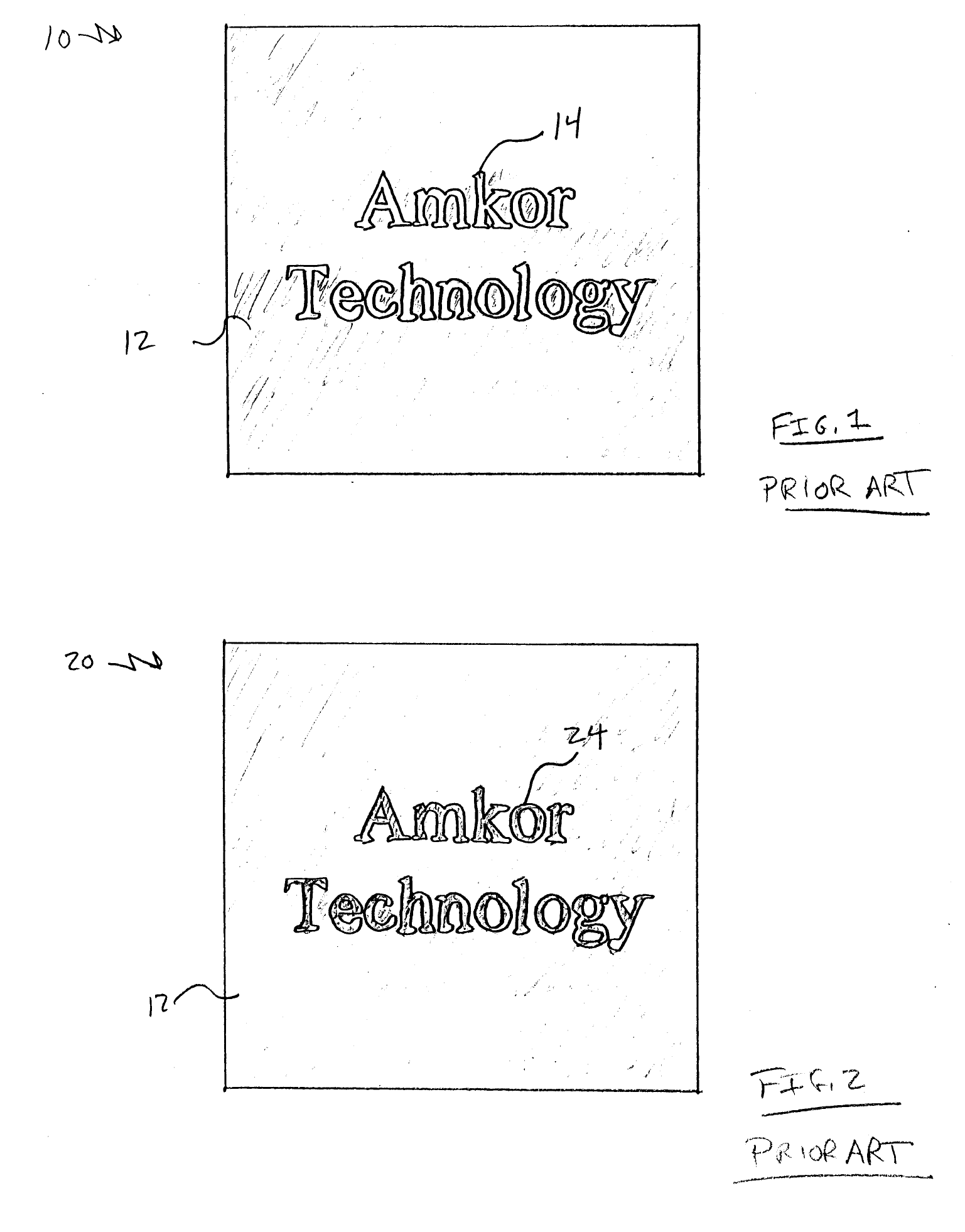

As discussed in greater detail below, formation of mark 330 is more reliable, less labor-intensive, and less expensive than formation of a prior art ink mark (see ink mark 14 of FIG. 1, for example). Further, changing to a different pattern than that of mark 330 involves only some relatively simple computer programming as compared to the formation of a new metal stencil for pad ink marking as in the prior art.

FIG. 5 is a cross-sectional of package 300 during fabrication in accordance with one embodiment of the present invention. As shown in FIG. 5, package 300 is supported in an ink marking apparatus 510 in a conventional manner, e.g., in a strip form.

Ink marking apparatus 510 includes a compliant pad 502. Compliant pad 502, e.g., formed of rubber, has ink 504 applied to a lower, e.g., first, surface 502L of compliant pad 502. Lower surface 502L is pressed against upper surface 312U of encapsulant 312. As those of skill in the art will understand, ink 504 is transferred from lower surface 502L of compliant pad 502 to upper surface 312U. In one embodiment, ink 504 is TPC 200 ink manufactured by Teca-Print, Inc. having a location at 10 Cook Street, Billerica MA 01821.

Advantageously, lower surface 502L of compliant pad 502 is smooth, i.e., is formed without a pattern. Accordingly, compliant pad 502 can be used with any one of a number of packages. In this manner, custom tooling associated with pad ink marking of the prior art is avoided. Since compliant pad 502 is compliant, lower surface 502L is planar or, alternately, is curved but complies to become planar when pressed against upper surface 312U of encapsulant 312 as illustrated in FIG. 5.

Generally, lower surface 502L of compliant pad 502 has a surface area less than or equal to the surface area of upper surface 312U of encapsulant 312. In this embodiment, lower surface 502L of compliant pad 502 is rectangular. To illustrate, lower surface 502L of compliant pad 502 is 15mm x 15mm and upper surface 312U of encapsulant 312 is 20mm x 20mm. However, in other embodiments, lower surface 502L of compliant pad 502 has a different shape, e.g., is circular or has at least one straight edge.

Ink 504 is cured to form contrast layer 320 (contrast layer 320 is illustrated in FIG. 6). For example, ink 504 is cured, e.g., by heating.

In one embodiment, ink marking apparatus 510 is a Markem 597 M/K ink marking apparatus having model number DPM-513SV manufactured by Markem Corporation of Keene, New Hampshire. Relevant specifications for various parameters for this embodiment are set forth below in Table 1.

TABLE 1

PARAMETER SPECIFICATION

Pad resting position 11.5 mm

Pad to plate 18.5 mm

Pad to product 89.5 mm

Pad/plate dwell time 0 sec

Pick up delay time 0 sec

Pad/product delay time 0.4 sec

Pad/plate speed up (down) 27 cm/sec

Pad/product speed up (down) 27 cm/sec

Plate speed out/in 19 cm/sec

Plate dwell 0 sec

Printer mode Normal

Trigger Source Remote

Trigger mode Continuous

Display unit Metric

Belt speed 1.5 - 3.0 m/min

Cure temperature 150-170 deg.

In an alternative embodiment, ink 504 is applied to upper surface 312U without using compliant pad 502, i.e., without using pad ink marking. For example, ink 504 is applied by ink spraying or ink rolling. In ink spraying, ink 504 is sprayed, e.g., from a nozzle, on upper surface 312U. In ink rolling, ink 504 is rolled, e.g., using a roller, on upper surface 312U.

FIG. 6 is a cross-sectional of package 300 of FIG. 5 at a further stage of fabrication. Referring now to FIG. 6, a laser marking apparatus 610 includes a laser 602. Generally, the pattern of mark 330 is loaded as software into laser marking apparatus 610 in a conventional manner. Based on this software, laser 602 is fired at contrast layer 320 to selectively remove, sometimes called laser ablate or etch, contrast layer 320 to form mark 330. More particularly, laser 602 is fired at contrast layer 320 to form a pattern, i.e., mark 330, in contrast layer 320 and through contrast layer 320.

Laser 602 penetrates through contrast layer 320 and into upper surface 312U of encapsulant 312 such that encapsulant 312 is visible through mark 330. For the same reason, mark 330 extends slightly into encapsulant 312. Although it is important that laser 602 penetrates through contrast layer 320, the depth to which laser 602 penetrates into upper surface 312U of encapsulant 312 is not of any particular importance. In one embodiment, laser 602 does not penetrate into upper surface 312U of encapsulant 312. In another embodiment, laser 602 slightly penetrates, i.e., scratches, into upper surface 312U of encapsulant 312 such that mark 330 is a scratching into upper surface 312U of encapsulant 312. Generally, the depth to which laser 602 penetrates into upper surface 312U of encapsulant 312 is sufficiently shallow to insure that laser 602 does not damage electronic component 302, bond wires 310, leads 308, or other critical structures of package 300.

In one embodiment, laser marking apparatus 610 is a Dong Yang M/K laser marking apparatus having model number DLM-812 manufactured by Dong Yang Corporation of Seoul, Korea. Relevant specifications for various parameters for this embodiment are set forth below in Table 2.

TABLE 2

PARAMETER SPECIFICATION

Power 7.5 watts (89%)

Pulse frequency 62 kHz

Pulse duration 8 us

Draw step 15 Least Step Bit (LSB)

Jump step 100 LSB

Step period 120 us

Corner delay 5 us

Advantageously, changing to a different pattern than that of mark 330 involves only some relatively simple computer programming of laser marking apparatus 610 as compared to the formation of a new metal stencil for pad ink marking as in the prior art. Thus, the method in accordance with the present invention is well suited for use in applications where the pattern of the mark on upper surface 314 of package 300 frequently changes. For example, the pattern of the mark frequently changes in applications involving advertisement by manufacturers.

Further, since encapsulant 312 is exposed through mark 330 and contrast layer 320 has a high contrast to encapsulant 312, mark 330 is readily visible. Thus, the top, i.e., upper surface 314, of package 300 is marked with a high visibility mark 330 at a minimal cost and a fast cycle time.

Although formation of mark 330 in contrast layer 320 by laser 602 is set forth above, in light of this disclosure, those of skill in the art will understand that other techniques to form a mark in contrast layer 320 can be used. For example, contrast layer 320 is mechanically etched with an engraver.

This application is related to Miks et al., commonly assigned and co-filed U.S. Patent Application Serial Number [ATTORNEY DOCKET NUMBER G0029M], entitled "REVERSE CONTRAST PACKAGE MARKING METHOD", which is herein incorporated by reference in its entirety.

The drawings and the forgoing description gave examples of the present invention. The scope of the present invention, however, is by no means limited by these specific examples. Numerous variations, whether explicitly given in the specification or not, such as differences in structure, dimension, and use of material, are possible. The scope of the invention is at least as broad as given by the following claims.

Claims

1. WE CLAIM:
1. A structure comprising:an electronic component;an encapsulant enclosing said electronic component, said encapsulant having a first surface;a contrast layer on said first surface; anda mark in said contrast layer.
2. The structure of Claim 1 wherein said encapsulant is a cured plastic encapsulant.
3. The structure of Claim 1 wherein said encapsulant is a cured liquid encapsulant.
4. The structure of Claim 1 wherein said first surface is planar.
5. The structure of Claim 1 wherein said contrast layer has a contrast relative to said encapsulant.
6. The structure of Claim 5 wherein said contrast layer is light in color and said encapsulant is dark in color.
7. The structure of Claim 6 wherein said contrast layer is white and said encapsulant is black.
8. The structure of Claim 1 wherein said contrast layer is formed on a central region of said first surface.
9. The structure of Claim 1 wherein said contrast layer entirely covers said first surface.
10. The structure of Claim 1 wherein said contrast layer is rectangular.
11. The structure of Claim 1 wherein said contrast layer is circular.
12. The structure of Claim 1 wherein a first surface of said contrast layer is on said first surface of said encapsulant.
13. The structure of Claim 12 wherein a second surface of said contrast layer is exposed to an ambient environment.
14. The structure of Claim 13 wherein said mark is an etching in said contrast layer, said mark extending from said first surface of said contrast layer to said second surface of said contrast layer.
15. The structure of Claim 14 wherein said encapsulant is visible through said mark.
16. The structure of Claim 1 wherein said contrast layer is a first contrast layer and said mark is a first mark, said encapsulant having a second surface, said structure further comprising:a second contrast layer on said second surface; anda second mark in said second contrast layer.
17. The structure of Claim 16 wherein said second surface is planar.
18. The structure of Claim 1 wherein said contrast layer has at least one straight edge.
19. The structure of Claim 1 wherein said mark extends into said encapsulant.
20. The structure of Claim 19 wherein said mark is a scratching into said first surface.
21. A structure comprising:a body having a first surface;a contrast layer on said first surface; anda mark in said contrast layer.
22. The structure of Claim 21 wherein said body is selected from the group consisting of ceramic, glass, plastic, metal, solder mask, silicon, wafer, printed circuit board, and encapsulant.
23. The structure of Claim 21 wherein said contrast layer has a contrast relative to said body.
24. The structure of Claim 21 wherein said body is visible through said mark.
25. The structure of Claim 21 wherein said first surface is planar.
26. The structure of Claim 21 wherein said contrast layer is light in color and said body is dark in color.
27. The structure of Claim 26 wherein said contrast layer is white and said body is black.
28. The structure of Claim 21 wherein said contrast layer is formed on a central region of said first surface.
29. The structure of Claim 21 wherein said contrast layer entirely covers said first surface.
30. The structure of Claim 21 wherein said contrast layer is rectangular.
31. The structure of Claim 21 wherein said contrast layer is circular.
32. The structure of Claim 21 wherein a first surface of said contrast layer is on said first surface of said body.
33. The structure of Claim 32 wherein a second surface of said contrast layer is exposed to an ambient environment.
34. The structure of Claim 33 wherein said mark is an etching in said contrast layer, said mark extending from said first surface of said contrast layer to said second surface of said contrast layer.
35. The structure of Claim 21 wherein said contrast layer is a first contrast layer and said mark is a first mark, said body having a second surface, said structure further comprising:a second contrast layer on said second surface; anda second mark in said second contrast layer.
36. The structure of Claim 35 wherein said second surface is planar.
37. The structure of Claim 21 wherein said contrast layer has at least one straight edge.
38. The structure of Claim 21 wherein said mark extends into said body.
39. The structure of Claim 38 wherein said mark is a scratching into said first surface.
